(19) United States
(12) Patent Application Publication
(10) Pub. No.: US 2024/0145236 A1
(43) Pub. Date: May 2, 2024

(54) SUBSTRATE PROCESSING METHOD

(71) Applicant: ASM IP Holding B.V., Almere (NL)

(72) Inventors: Hyunchul Kim, Hwaseong-si (KR); Ryu Nakano, Sagamihara-shi (JP); KiHun Kim, Yongin-si (KR); Rin Ha, Hwaseong-si (KR)

(21) Appl. No.: 18/383,109

(22) Filed: Oct. 24, 2023

Related U.S. Application Data
(60) Provisional application No. 63/419,949, filed on Oct. 27, 2022.

(51) Int. Cl. H01L 21/02; C23C 16/04; C23C 16/40; C23C 16/455

(52) U.S. Cl. CPC H01L 21/0228; C23C 16/045; C23C 16/402; C23C 16/45536; H01L 21/02164; H01L 21/02274

(57) ABSTRACT

Provided is a method for improving the inhibiting characteristics in the upper portion of the gap. In one embodiment of the disclosure, a first inhibitor and a second inhibitor are supplied, therefore more inhibiting radicals may be generated and remove more reaction activation sites from the upper portion of the gap and improve the inhibiting characteristics in the upper portion compared to in the lower portion. The substrate processing method of the disclosure may facilitate further filling the gap with negative slope and complex structure.

### CROSS-REFERENCE TO RELATED APPLICATIONS

This application claims priority to U.S. Provisional Patent Application Ser. No. 63/419,949 filed Oct. 27, 2022 and titled SUBSTRATE PROCESSING METHOD, the disclosure of which is hereby incorporated by reference in its entirety.

### FIELD OF INVENTION

The disclosure relates to a method for filling a gap without forming a void in the gap, and more specifically to a method for controlling a forming a film at the upper portion of the gap to fill the gap more effectively without forming a void therein.

### BACKGROUND OF THE DISCLOSURE

In gap fill process to a semiconductor device, the profile of the gap structure is an important process factor for effective gap fill process. For instance, a gap structure with low aspect ratio or positive slope may be filled easily without forming a void in it. FIG. 1(A) and FIG. 1(B) illustrate a conventional method for filling a gap 1 with a low aspect ratio and a positive slope respectively. However, as the line width of the circuit of the semiconductor device becomes narrower, a device structure of the semiconductor device may be more complex, and therefore, a gap structure with high aspect ratio and negative slope may be introduced.

As the line width of the circuit of the semiconductor device becomes narrower, an atomic layer deposition (ALD) method was introduced as a gap fill process. The ALD method may facilitate a precise control of the film thickness. However, a fast gas exchange in ALD method may result in different film growth rate between an upper portion and a lower portion of the gap, leading to an overhang in the upper portion and a void formation inside of the gap.

FIG. 2(A) and FIG. 2(B) illustrate examples of an overhang 2 and a void 3 occurred in a gap with high aspect ratio and negative slope respectively. Incomplete gap fill and formation of void in a gap may lower the mechanical strength of the film filling the gap, causing cracks and deterioration of the dielectric characteristics.

To address the cracks and deterioration, an inhibitor such as N₂ was introduced. The inhibitor may suppress a film from being formed in the upper portion of the gap and lower a film growth rate thereon, so a gap fill process may be more facilitated. FIG. 3(A) to FIG. 3(D) illustrate a conventional gap fill process using a plasma atomic layer deposition (PEALD) method and an inhibitor.

In FIG. 3(A) to FIG. 3(D), a film 4 may be formed on the surface of the gap by PEALD method (FIG. 3(A)), followed by forming an inhibiting layer 5 in the upper portion of the gap by supplying a N₂ inhibitor (FIG. 3B)). The steps FIG. 3(A) and FIG. 3(B) may be repeated and the width of the upper portion may become wider than that of the bottom, and the gap may be filled without forming a void (FIG. 3(C) and FIG. 3(D)). However, as the aspect ratio of the gap becomes higher and the profile of the gap structure becomes more complex, it becomes harder to fill the gap using the method illustrated in FIG. 3(A) to FIG. 3(D). Therefore, a method of filling a gap using an inhibiting layer that enables to fill the gap having a negative slope or a complex structure (e.g. non-straight profile structure) more effectively without forming a void is desired.

### SUMMARY OF THE DISCLOSURE

In one or more embodiments, a gap fill process may be carried out by plasma enhanced atomic layer deposition. In more detail, the gap fill process may include a step of forming a film and a step of inhibiting.

In one or more embodiments, the step of forming the film on the substrate may comprise a step of supplying a source gas and a step of supplying a reactant gas sequentially and alternately.

In one or more embodiments, in the step of supplying a source gas and the step of supplying a reactant gas, the source gas may contain silicon and the reactant may contain oxygen.

In one or more embodiments, the step of inhibiting may comprise a step of supplying inhibitors to the substrate and a step of activating the inhibitors.

In one or more embodiments, the step of supplying inhibitors may comprise supplying a first inhibitor and supplying a second inhibitor.

In one or more embodiments, the first inhibitor may comprise a nitrogen-containing gas and the second inhibitor may comprise a hydrogen-containing gas.

In one or more embodiments, supplying the first inhibitor and supplying the second inhibitor may be carried out sequentially and alternately.

In one or more embodiments, the reactant and the inhibitor may be activated by applying a RF power to the reactor. The RF power to activate the reactant may be high frequency RF power and the RF power to activate the inhibitors may be low frequency RF power.

In one or more embodiments, the gap fill process may comprise a super cycle comprising the step of forming the film and the step of inhibiting, wherein the step of forming the film may be repeated more than one time and the step of inhibiting may be repeated more than one time, and the super cycle is repeated more than one time.

In one or more embodiments, at least a portion the gap may have a negative slope or a complex structure such as non-straight profile structure.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIGS. 1(A) and (B) illustrate a conventional method for filling a gap with a low aspect ratio or a positive slope.

FIGS. 2(A) and (B) illustrate overhangs occurred in a gap with high aspect ratio and negative slope respectively in conventional method for filling a gap.

FIG. 3(A) to (D) illustrate a gap fill process using a nitrogen inhibitor in conventional method for filling a gap.

FIG. 4 illustrates a method for processing a substrate for filling a gap according to at least one embodiment of the disclosure.

FIG. 5 illustrates a timing graph for filling a gap with a silicon oxide film according to at least one embodiment of the disclosure.

FIG. 6 illustrates a timing graph for filling a gap according to another embodiment.

FIG. 7 illustrates a timing graph for filling a gap according to another embodiment.

FIG. 8 illustrates an inhibiting mechanism when providing only N₂ as a single inhibitor.

FIG. 9 illustrates an inhibiting mechanism when providing a nitrogen-containing gas and a hydrogen-containing gas as inhibitors.

FIG. 10(A) to (D) show TEM images of SiO₂ film formed on the gap with negative slope depending on the type of inhibitor and a relative deposition rate by position.

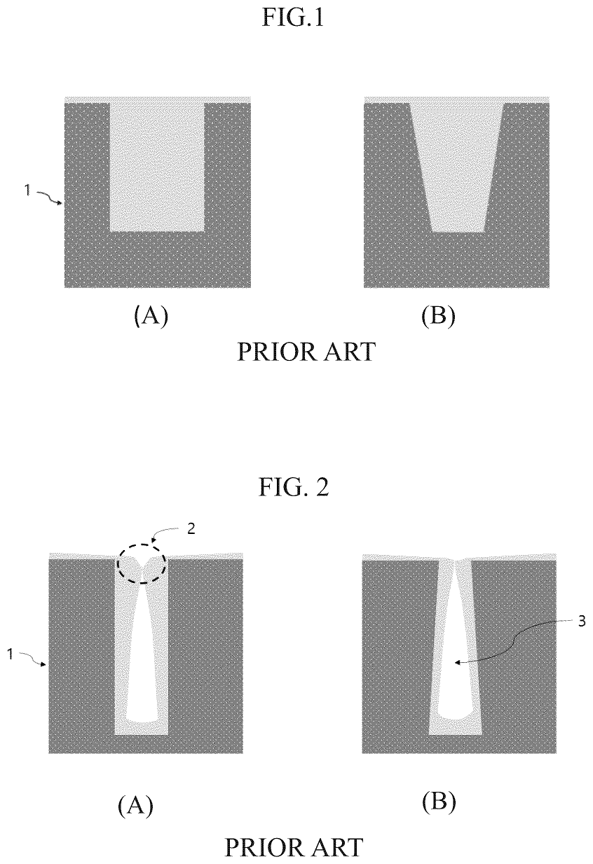

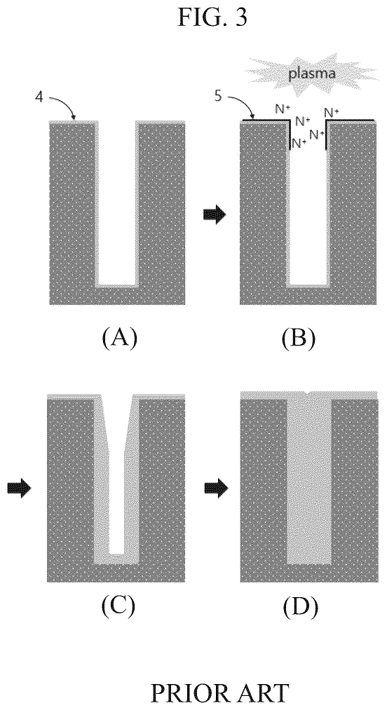

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

The disclosure provides a method for suppressing a film from being formed in the upper portion of the gap more effectively in filling a gap, more specifically in a gap with high aspect ratio or in a gap which may have a negative slope in at least a portion of the gap structure.

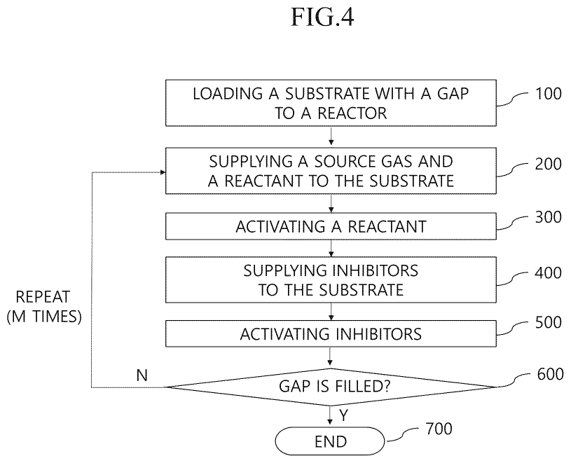

FIG. 4 illustrate a method for processing a substrate for filling a gap according to an embodiment.

Each step of FIG. 4 is described in more detail as follows.

A step of loading a substrate 100: In the step 100, a substrate may be loaded onto a substrate support unit of the reactor (not shown). The substrate may comprise a gap including a trench. The substrate support unit may comprise a susceptor mounted thereon and the substrate may be loaded onto the susceptor. The substrate support unit may further comprise a heating block. The heating block may heat the substrate to a set temperature. The substrate support unit itself may be the heating block such that the susceptor may be omitted and the substrate may be loaded onto the heating block directly. The reactor may comprise a gas supply unit and a substrate support unit facing the gas supply unit. At least one of the gas supply unit and the substrate support unit may be connected to an RF power generator and act as an electrode. In this case, the gas supply unit may be referred to as an upper electrode and the substrate support unit may be referred to as a lower electrode. The upper electrode and the lower electrode may form a reaction space formed therebetween.

A step of suppling a source gas and a reactant 200: In the step 200, a source gas and a reactant may be supplied to the substrate loaded to the reactor. The source gas and the reactant may be supplied simultaneously, but not react chemically each other. But in the next step 300 as described later the activated reactant may react chemically with the source gas and form a compound on the substrate. Therefore, in the step 200 the reactant may act as a reactive purge gas. The source gas supplied may be adsorbed on the substrate. In another embodiment, the source gas and the reactant may be supplied sequentially and alternately, not supplying simultaneously. The source gas may comprise a silicon-containing precursor and the reactant may comprise an oxygen-containing precursor.

A step of activating a reactant 300: In the step 300, a reactant may be continuously supplied to the reaction space and activated by applying an energy to at least one of the upper electrode and the lower electrode forming the reaction space. The applied energy may be from at least one of direct plasma, remote plasma, neutral beam, UV and any other external energy source corresponding to them. The activated reactant may react chemically with the source gas adsorbed on the substrate and form a compound thereon. In an embodiment, the compound formed on the substrate may be an insulating film, e.g. silicon oxide (SiO₂). The step of supplying a reactant and a reactant 200 and a step of activating a reactant 300 may be referred to as a step of forming a film.

A step of supplying inhibitors 400 and a step of activating the inhibitors 500: In the steps 400 and 500, the inhibitors may be supplied continuously to the substrate and activated. To activate the inhibitors, at least one of direct plasma, remote plasma, neutral beam, UV and any other external energy source may be applied to the reactor. The activated inhibitors may remove the reaction activation sites (e.g. hydroxyl groups such as OH—), from the surface of the compound formed on the substrate. The step of supplying inhibitors 400 and the step of activating the inhibitors 500 may be referred to as a step of inhibiting.

The aforementioned reaction activation sites may react with the source gas supplied during the next cycle and enable a film to be formed and grow. For instance, the activated oxygen gas may be supplied to the silicon source gas adsorbed on the substrate and a silicon oxide film may be formed. During formation of a silicon oxide film, the reaction activation sites (e.g. hydroxyl groups such as OH—) may be formed on the surface of the silicon oxide film. The reaction activation sites may react chemically with the silicon source gas supplied in the next cycle, form a silicon-oxygen-silicon (Si—O—Si) bonding bridge structure and promote the film to continue to grow.

The inhibitors may react with the hydrogen comprising the reaction activation sites and inhibit the film from being formed thereon. In the disclosure, a plurality of inhibitors, for instance, at least more than two inhibitors may be supplied to further enhance the capabilities to remove the reaction activation sites and inhibit the formation of the film. In an embodiment of the disclosure, to further facilitate removing the hydroxyl groups (OH—) from the surface of the silicon oxide film, a nitrogen-containing gas as a first inhibitor and a hydrogen-containing gas as a second inhibitor may be supplied.

In FIG. 4, the inhibitors (e.g. both a nitrogen-containing gas and a hydrogen-containing gas) may be supplied first during the step 400 (pre-flow) to stabilize the pressure in the reaction space, then a RF power may be applied during the step 500. However, in another embodiment of the disclosure, the step of supplying the inhibitors 400 and the step of activating the inhibitors 500 may be carried out simultaneously without pre-flowing the inhibitor.

A step of filling a gap 600 and 700: The step of supplying a source gas and a reactant 200, a step of activating the reactant 300, a step of supplying the inhibitors 400 and a step of activating the inhibitors 500 may be carried out and the gap may be filled with the film 600. If the gap is fully filled with the film, the gap fill process may end 700. If the gap is not filled with the film, the step of supplying a source gas and a reactant 200, a step of activating the reactant 300, a step of supplying inhibitors 400 and a step of activating the inhibitors 500 may be repeated a plurality of times (e.g. M times).

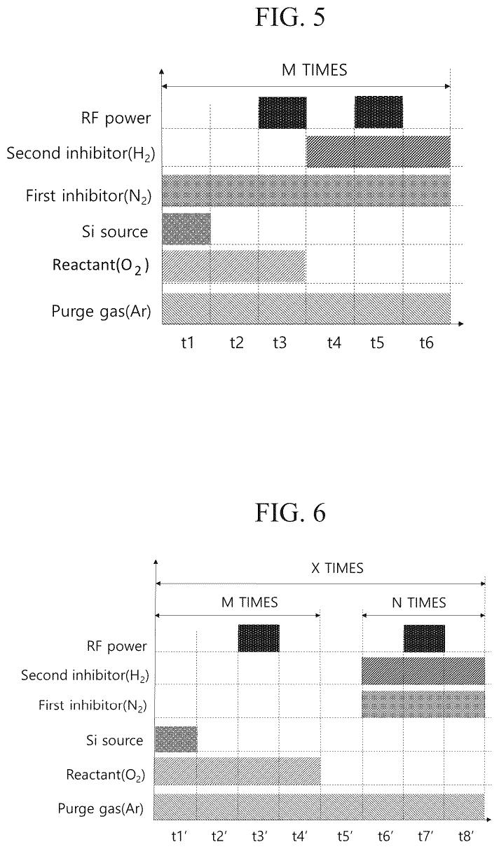

FIG. 5 illustrates a timing graph for filling a gap with a silicon oxide film according to an embodiment.

The gap fill process according to FIG. 5 may comprise a step of forming a film on the surface of the gap and a step of supplying inhibitors. Each step will be described in more detail as follows.

A step of forming a film (t1 to t3): In the steps t1 to t3, a source gas and a reactant may be supplied sequentially and alternately, and a film may be formed on the gap structure. The source gas may comprise a silicon-containing precursor and the reactant may comprise a oxygen-containing precursor, and the film formed on the gap structure may be a silicon oxide (SiO₂). The reactant may be activated by RF power applied to the reactor and react chemically with the source gas adsorbed on the substrate in order to form the film. After supplying the source gas and the reactant, a purge step (t2, t4) may be further provided to remove a residual gas from the reactor.

In an embodiment, a high frequency RF power (HRF) and a low frequency RF power (LRF) may be applied together to activate the reactant. The HRF may increase the amount of ions and radicals and the LRF may facilitate ions and radicals to travel to the lower portion of the gap. In an embodiment according to the disclosure, the range of frequency of HRF may be 10 MHz to 100 MHz, more specifically 30 MHz to 60 MHz, and the range of frequency of LRF may be 100 kHz to 800 kHz, more specifically 300 kHz to 500 kHz.

A step of supplying inhibitors (t4 to t6): In the steps t4 to t6, a plurality of inhibitors may be supplied to the film formed on the gap structure. In an embodiment of the disclosure according to FIG. 5, a nitrogen-containing gas (e.g. N₂) as a first inhibitor and a hydrogen-containing gas (e.g. H₂) as a second inhibitor may be supplied. The inhibitors supplied to the substrate may form a deposition inhibiting area in the upper portion of the gap and inhibit a source gas from adsorbing thereon.

To form more inhibiting area in the upper portion of the gap than in the lower portion of the gap, inhibitors may be activated by applying a high frequency RF power (HRF). Active species such as ions and radicals activated by HRF may have a short mean free path, therefore, inhibitors activated by HRF may react with the source gas adsorbed on the upper portion of the gap more than in the lower portion of the gap. In an embodiment, the frequency of RF power applied in the steps of activating inhibitors may be higher than 13 MHz, more specifically 30 MHz to 60 MHz.

An only nitrogen-containing gas (e.g. N₂) is supplied as a single inhibitor in the existing gap fill process, but in an embodiment according to the disclosure a hydrogen-containing gas as well as a nitrogen-containing gas may be supplied as inhibitors to improve much more the inhibiting characteristics. The reaction mechanism occurring when supplying a plurality of inhibitors will be described in more detail later.

The gap may be filled with the film by repeating the step of forming a film (t1 to t3) and the step of supplying inhibitors (t4 to t6) a plurality of times (M times). In an embodiment according to FIG. 5, an Ar gas may be continuously supplied as a purge gas. In another embodiment, a hydrogen-containing gas (e.g. H₂) may be continuously supplied throughout the step of forming a film and the step of supplying inhibitors (t1 to t6).

In another embodiment of FIG. 5, the step of forming a film (t1 to t3) may be repeated at least one time as a sub-cycle and the step of supplying inhibitors (t4 to t6) may be repeated at least one time as a sub-cycle, and a super-cycle comprising sub-cycles, i.e. the step of forming a film and the step of supplying inhibitors, may be repeated a plurality of times.

FIG. 6 illustrates a modification of the embodiment of FIG. 5. In FIG. 6, a purge step (t5′) may be provided between a step of forming a film (t1′ to t4′) and a step of supplying inhibitors (t6′ to t8′), and nitrogen-containing gas (e.g. N₂) as the first inhibitor and hydrogen-containing gas (e.g. H₂) as the second inhibitor may be supplied only in the step of supplying inhibitors.

In FIG. 6, a step of forming a film (t1′ to t4′) may be repeated at least one time and after that, a purge step (t5′) may be carried out. The purge step (t5′) may be carried out by supplying a purge gas such as Ar or by vacuum purge. The purge step (t5′) may remove a residual gas, and therefore, facilitate further the reaction between a film and inhibitors which may be supplied in the next step of supplying inhibitors. After that, the step of supplying inhibitors (t6′ to t8′) may be repeated at least one time. In addition, a super cycle comprising sub-cycles such as the step of forming a film and the step of supplying inhibitors may be repeated at least one time (X times).

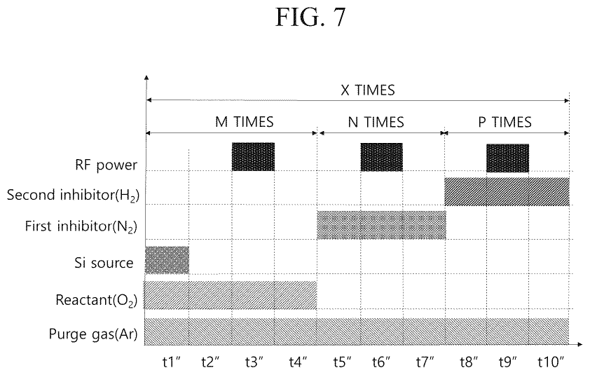

FIG. 7 illustrates another modification of the embodiment of FIG. 5. In FIG. 7, a step of supplying a first inhibitor (t5″ to t7″) and a step of supplying a second inhibitor (t8″ to t9″) may be carried out sequentially.

In FIG. 5, FIG. 6 and FIG. 7, two different inhibitors may be supplied, but the number of inhibitors may not be limited thereto. For instance, more than two inhibitors may be supplied (e.g. three or four inhibitors) to strengthen the inhibiting characteristics further in the upper portion of the gap.

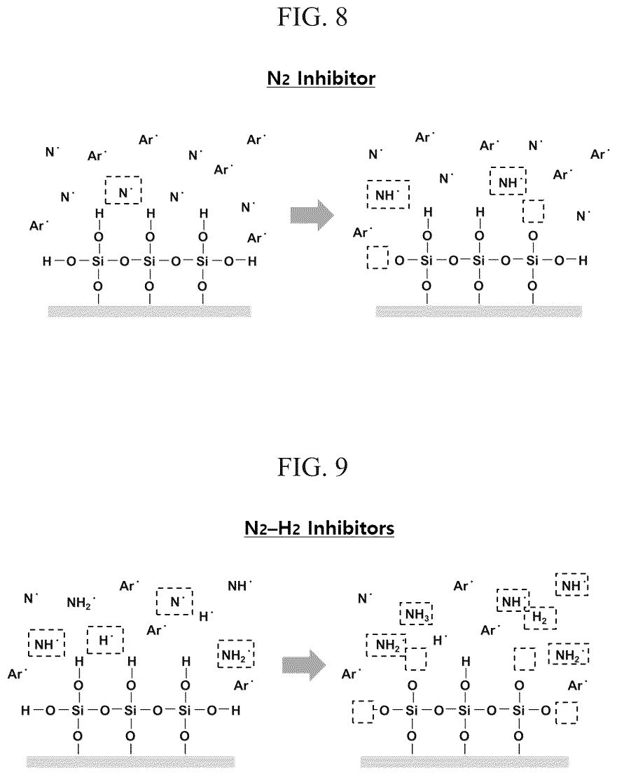

FIG. 8 and FIG. 9 illustrate the difference of inhibiting characteristics when only N₂ is supplied as a single inhibitor as shown in FIG. 8 and when a nitrogen-containing gas (e.g. N₂) as a first inhibitor and a hydrogen-containing gas (e.g. H₂) as a second inhibitor are supplied as shown in FIG. 9, when forming SiO₂ film on the substrate.

In FIG. 8, when an activated N₂ gas is supplied as a single inhibitor, a hydrogen (H) in hydroxyl group (i.e. OH—) on the surface of SiO₂ film may react with a nitrogen radical (N*) and form a compound (e.g. NH*) comprising a nitrogen and a hydrogen marked as a dashed rectangle. A hydrogen in hydroxyl group (i.e. OH—) on the surface of SiO₂ film may act as a reaction activation site for forming SiO₂ film. In more detail, a hydrogen of the ligand may react with a silicon source gas at the next cycle and form Si—O—Si bonding structure, and this cycle may be repeated and the SiO₂ film may continue to grow accordingly. However, if a hydrogen in the hydroxyl group reacts with an inhibitor, the reaction activation sites (e.g. OH—) may be removed and it may result in inhibiting the formation of Si—O—Si bonding structure and SiO₂ film.

In FIG. 9, a nitrogen (N₂) gas as a first inhibitor and a hydrogen (H₂) gas as a second inhibitor may be activated and supplied together. The mixture of activated nitrogen and activated hydrogen may comprise a nitrogen radical (e.g. N*), a hydrogen radical (e.g. H*) and a nitrogen-hydrogen compound radical (e.g. NH*, NH₂*). On the other hand, a hydrogen in hydroxyl group on the surface of SiO₂ film may react with a nitrogen radical, a hydrogen radical and a nitrogen-hydrogen compound radical and form a nitrogen-hydrogen compound (e.g. NH*, NH₂*, NH₃) and/or a hydrogen (H₂) marked as a dashed rectangle.

In FIG. 9, when a nitrogen and a hydrogen are supplied together as inhibitors, more various type of inhibiting radicals may be generated and react with more hydrogens in hydroxyl groups on the surface of SiO₂ film. Therefore, more reaction activation sites (i.e. hydrogen in the hydroxyl group) may be removed, the inhibiting characteristics may be enhanced and a film formation on the substrate may become harder. According to FIG. 5, FIG. 6, FIG. 7 and FIG. 9, supplying a plurality of inhibitors such as N₂ and H₂ may have a technical advantage of improving inhibiting characteristics in the upper portion compared to in the lower portion of the gap.

Table 1 shows a type of nitrogen-containing radicals which may be generated in FIG. 8 and FIG. 9.

TABLE 1
inhibition radicals generated in FIG. 8 and FIG. 9

| | N₂ inhibitor | N₂—H₂ inhibitors |
|---|---|---|
| | in FIG. 8 | in FIG. 9 |
| Inhibiting radicals | N* | N*, NH*, NH₂*, H* |

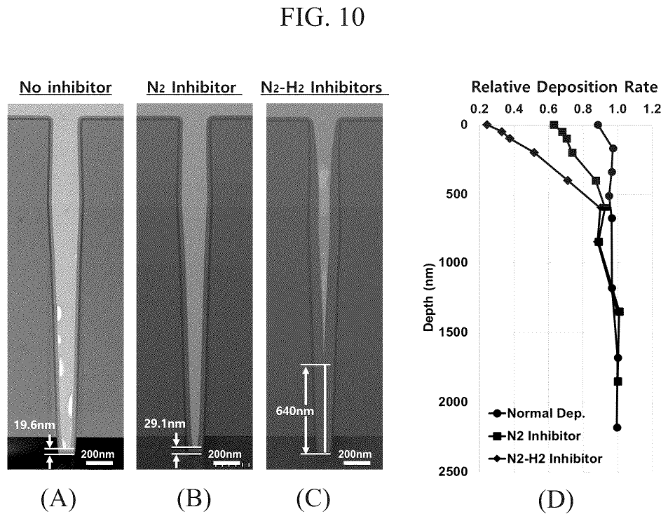

FIG. 10(A) to FIG. 10(C) are TEM (Transmission Electron Microscope) images of SiO₂ film profile formed on the gap structure with negative slope depending on the type of inhibitor and FIG. 10(D) illustrates a relative deposition rate of SiO₂ film by position on the gap for each condition of FIG. 10(A), FIG. 10(B) and FIG. 10(C). FIG. 10(A) shows a SiO₂ film profile formed on the gap by PEALD method without supplying an inhibitor. FIG. 10(B) shows a SiO₂ film profile formed on the gap by PEALD method and only activated nitrogen (N₂) gas is supplied as an inhibitor. FIG. 10(C) shows a SiO₂ film profile formed on the gap by PEALD method and an activated nitrogen (N₂) gas and an activated hydrogen (H₂) gas are supplied as inhibitors.

In FIG. 10(A), when an inhibitor is not supplied, a SiO₂ film with uniform thickness (19.6 nm) is formed along the surface of the gap from the upper portion to the lower portion of the gap. In FIG. 10(B), when only activated N₂ gas is supplied as an inhibitor, a thicker SiO₂ film (29.1 nm) may be formed in the lower portion than in the upper portion of the gap. In FIG. 10(C), when an activated nitrogen gas (N₂) and an activated hydrogen gas (H₂) are supplied as inhibitors, much thicker SiO₂ film (640 nm) may be formed in the lower portion than in the upper portion, compared to FIG. 10(B). Therefore, the effectiveness of inhibiting characteristics in the upper portion over the lower portion in FIG. 10(C) is higher than that in FIG. 10(B).

FIG. 10(D) illustrates a relative deposition rate of SiO₂ film by position on the gap for each condition of FIG. 10(A), FIG. 10(B) and FIG. 10(C). As shown in FIG. 10(D), when an activated nitrogen (N₂) gas and an activated hydrogen (H₂) gas are supplied, the relative deposition rate of SiO₂ film in the upper portion over the lower portion may be the lowest. In other word, a N₂—H₂ inhibitor may generate more various radicals and remove more reaction activation sites (e.g. a hydrogen in hydroxyl group) and, therefore, the inhibiting characteristics may be greater than supplying only N₂ inhibitor. In addition, the slope of the film on the gap may become more positive slope according to the substrate processing method of the disclosure, therefore a gap in which at least a portion of the gap structure may have a negative slope and/or a complex structure such as non-straight profile structure may be filled without forming a void therein.

Table 2 shows a substrate processing conditions for an embodiment of the disclosure.

TABLE 2
a substrate processing conditions for an embodiment of the disclosure

| Process parameter | | Condition |
|---|---|---|
| Gas flow | Source carrier Ar | 1,000 to 5,000 (preferably 1,500 to 4,500) |
| (sccm) | Purge Ar | 500 to 3,000 (preferably 1,000 to 2,000) |
| | O₂ (Reactant) | 500 to 2,000 (preferably 1,000 to 1,500) |
| | N₂ (First inhibitor) | 500 to 2,000 (preferably 1,000 to 1,500) |
| | H₂ (Second inhibitor) | 500 to 2,000 (preferably 1,000 to 1,500) |
| RF frequency | HRF | 10 to 100 MHz (preferably 30 to 60 MHz) |
| | LRF | 100 to 800 kHz (preferably 300 to 500 kHz) |
| RF power (W) | HRF | 100 to 1,500 W (preferably 300 to 1,000 W) |
| | LRF | 30 to 300 W (preferably 50 to 200 W) |
| Step time/ | Source feeding | 0.1 to 1.0 (preferably 0.2 to 0.8) |
| cycle (sec) | Source purge | 0.1 to 1.0 (preferably 0.2 to 0.8) |
| | RF- On for activating | 0.1 to 1.0 (preferably 0.2 to 0.8) |
| | reactant | |
| | Purge | 0.1 to 1.0 (preferably 0.2 to 0.8) |
| | Rf-On for activating | 0.1 to 4.0 (preferably 0.2 to 2.0) |
| | inhibitors | |

| | |
|---|---|
| Process temperature (° C.) | 300 to 500 (preferably 350 to 450) |
| Silicon source | Aminosilane, |

A silicon-containing source for processing a substrate according to an embodiment of the disclosure and Table 2 may be at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; DIPAS, SiH₃N(iPr)₂; TEOS, Si(OEt)₄; SiCl₄; HCD, Si₂C₁₆; 3DMAS, SiH(N(Me)₂)₃; BEMAS, SiH₂[N(Et)(Me)]₂; AHEAD, Si₂(NHEt)₆; TEAS, Si(NHEt)₄; Si₃H₈; DCS, SiH₂Cl₂; SiHI₃; SiH₂I₂; or a mixture thereof.

An oxygen-containing gas for processing a substrate according to an embodiment of the disclosure and Table 2 may be at least one of O₂, O₃, CO₂, H₂O, NO₂, N₂O, radicals thereof, or a mixture thereof.

A nitrogen-containing gas as an inhibitor for processing a substrate according to an embodiment of the disclosure and Table 2 may be at least one of N₂, N₂O, NO₂, NH₃, N₂H₂, N₂H₄, radicals thereof, or a mixture thereof.

A hydrogen-containing gas as an inhibitor for processing a substrate according to an embodiment of the disclosure and Table 2 may be at least one of H₂, monoatomic hydrogen (H), radicals thereof, or a mixture thereof.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A method for filling a gap of a substrate, comprising:
a step of loading a substrate to a reactor;
a step of forming a film on the substrate, wherein the step of forming the film on the substrate is comprised of a step of supplying a source gas and a step of supplying a reactant gas sequentially and alternately; and
a step of inhibiting comprising:
a step of supplying inhibitors to the substrate; and
a step of activating the inhibitors.

2. The method of claim 1, wherein the step of supplying inhibitors further comprises supplying a first inhibitor and supplying a second inhibitor.

3. The method of claim 1, wherein the reactant gas and the inhibitors are activated by applying a RF power to a reactor.

4. The method of claim 3, wherein the RF power to activate the reactant is high frequency RF power.

5. The method of claim 4, wherein the frequency of RF power is between 10 MHz to 100 MHz.

6. The method of claim 5, wherein the frequency of RF power is between 30 MHz to 60 MHz.

7. The method of claim 3, wherein the RF power to activate the inhibitors is low frequency RF power.

8. The method of claim 7, wherein the frequency of RF power is between 100 kHz to 800 kHz.

9. The method of claim 8, wherein the frequency of RF power is between 300 kHz to 500 kHz.

10. The method of claim 1, further comprising a purge step after the step of forming a film on the substrate.

11. The method of claim 2, wherein supplying the first inhibitor and supplying the second inhibitor are carried out sequentially and alternately.

12. The method of claim 2, wherein the first inhibitor comprises a nitrogen-containing gas and the second inhibitor comprises a hydrogen-containing gas.

13. The method of claim 12, wherein the first inhibitor comprises at least one of: N₂, N₂O, NO₂, NH₃, N₂H₂, N₂H₄, radicals thereof, or a mixture thereof.

14. The method of claim 12, wherein the second inhibitor comprises at least one of: Hz, monoatomic hydrogen, radicals thereof, or a mixture thereof.

15. The method of claim 1, wherein the source gas contains silicon and the reactant contains oxygen.

16. The method of claim 15, wherein the source gas comprises at least one of: TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; DIPAS, SiH₃N(iPr)₂; TEOS, Si(OEt)₄; SiCl₄; HCD, Si₂Cl₆; 3DMAS, SiH(N(Me)₂)₃; BEMAS, SiH₂[N(Et)(Me)]₂; AHEAD, Si₂(NHEt)₆; TEAS, Si(NHEt)₄; Si₃H₈; DCS, SiH₂Cl₂; SiHI₃; SiH₂I₂; or a mixture thereof.

17. The method of claim 15, wherein the reactant comprises at least one of: O₂, O₃, CO₂, H₂O, NO₂, N₂O, radicals thereof; or a mixture thereof.

18. The method of claim 1, wherein the method comprises a super cycle comprising the step of forming the film and the step of inhibiting,
wherein the step of forming the film is repeated more than one time and the step of inhibiting is repeated more than one time,
wherein the super cycle is repeated more than one time.

19. The method of claim 1, wherein at least a portion of the gap has a negative slope or non-straight profile structure.
